(19) United States
(12) Patent Application Publication
(10) Pub. No.: US 2026/0107473 A1
(43) Pub. Date: Apr. 16, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Seong Hyun HWANG, Icheon-si (KR); Jeong Ho YEON, Icheon-si (KR)

(21) Appl. No.: 19/185,710

(22) Filed: Apr. 22, 2025

(30) Foreign Application Priority Data
Oct. 11, 2024 (KR) 10-2024-0138722

(51) Int. Cl. H10B 63/10; H10N 70/00; H10N 70/20

(52) U.S. Cl. CPC H10B 63/10; H10N 70/063; H10N 70/231; H10N 70/8265

(57) ABSTRACT

A semiconductor device includes first conductive lines each extending in a first direction, second conductive lines positioned on the first conductive lines and each extending in a second direction intersecting the first direction, memory cells respectively positioned between the first conductive lines and the second conductive lines, and each including a variable resistance pattern, a first gap-fill pattern positioned between an adjacent pair of the first conductive lines in the second direction, a second gap-fill pattern positioned on the first gap-fill pattern, and a third gap-fill pattern positioned between the first gap-fill pattern and the second gap-fill pattern, the third gap-fill pattern having a first interface with the first gap-fill pattern and a second interface with the second gap-fill pattern. The first interface is positioned below a lower surface of the variable resistance pattern, and the second interface is positioned above an upper surface of the variable resistance pattern.

### CROSS-REFERENCE TO RELATED APPLICATION

This application claims priority under 35 U.S.C. § 119 to Korean Patent Application No. 10-2024-0138722 filed on Oct. 11, 2024, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include first conductive lines each extending in a first direction, second conductive lines positioned on the first conductive lines and each extending in a second direction that intersects the first direction, memory cells respectively positioned between the first conductive lines and the second conductive lines, and each including a variable resistance pattern, a first gap-fill pattern positioned between an adjacent pair of the first conductive lines in the second direction, a second gap-fill pattern positioned on the first gap-fill pattern, and a third gap-fill pattern positioned between the first gap-fill pattern and the second gap-fill pattern, the third gap-fill pattern having a first interface with the first gap-fill pattern and a second interface with the second gap-fill pattern. The first interface is positioned below a lower surface of the variable resistance pattern, and the second interface with the second gap-fill pattern is positioned above an upper surface of the variable resistance pattern.

According to an embodiment of the present disclosure, a semiconductor device may include first conductive lines each extending in a first direction, second conductive lines positioned on the first conductive lines and each extending in a second direction that intersects the first direction, memory cells respectively positioned between the first conductive lines and the second conductive lines, and each including a variable resistance pattern, a first gap-fill pattern positioned between an adjacent pair of the first conductive lines in the second direction, and each including an oxide, and a third gap-fill pattern positioned on the first gap-fill pattern. The third gap-fill pattern has a lower surface positioned below a lower surface of the variable resistance pattern, and has an upper surface positioned above an upper surface of the variable resistance pattern.

According to an embodiment of the present disclosure, a method of manufacturing a semiconductor device may include forming a variable resistance layer on a first conductive layer, forming variable resistance lines by etching the variable resistance layer, forming first conductive lines each extending in a first direction by etching the first conductive layer, forming a first gap-fill pattern between an adjacent pair of the first conductive lines so that an upper surface of the first gap-fill pattern is positioned below a lower surface of each of an adjacent pair of the variable resistance lines, and forming a second gap-fill pattern on the first gap-fill pattern so that an upper surface of the second gap-fill pattern is positioned above an upper surface of each of the adjacent pair of the variable resistance lines.

### BRIEF DESCRIPTION OF THE DRAWINGS

FIGS. 1A, 1B, and 1C are drawings illustrating a semiconductor device according to an embodiment of the present disclosure.

FIGS. 2A, 2B, and 2C are drawings illustrating a semiconductor device according to an embodiment of the present disclosure.

FIGS. 3A and 3B are drawings illustrating a semiconductor device according to an embodiment of the present disclosure.

FIGS. 4A, 4B, 5A, 5B, 6A, 6B, 7A, 7B, 8A, 8B, 9A, 9B, 10A, and 10B are drawings illustrating a method of manufacturing a semiconductor device according to an embodiment of the present disclosure.

FIGS. 11A, 11B, 12A, 12B, 13A, 13B, 14A, 14B, 15A, 15B, 16A, and 16B are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to the present technology, a semiconductor device having a stable structure and improved reliability may be provided. Throughout the specification and claims, a list of items prefaced by a phrase such as “at least one of” or “one or more of” or “one or both of” indicates an inclusive list. For example, a list of “at least one of A or B” and a list of “one or both of A and B” each indicate A, or B, or AB (i.e., A and B). Moreover, a first element “on” a second element indicates that the first element can be “directly on” the second element, or that at least one intervening element can be interposed between the first and second elements.

Hereinafter, embodiments according to the technical spirit of the present disclosure are described with reference to the accompanying drawings.

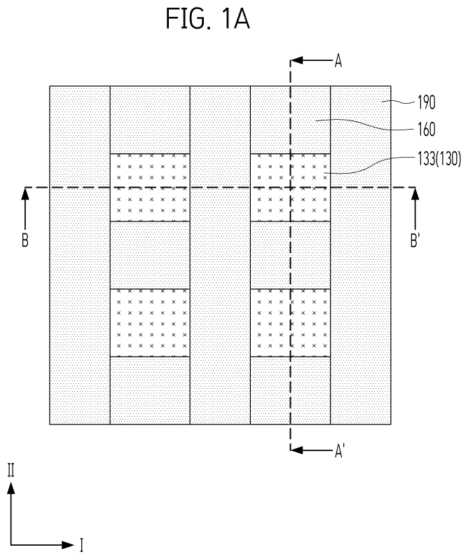

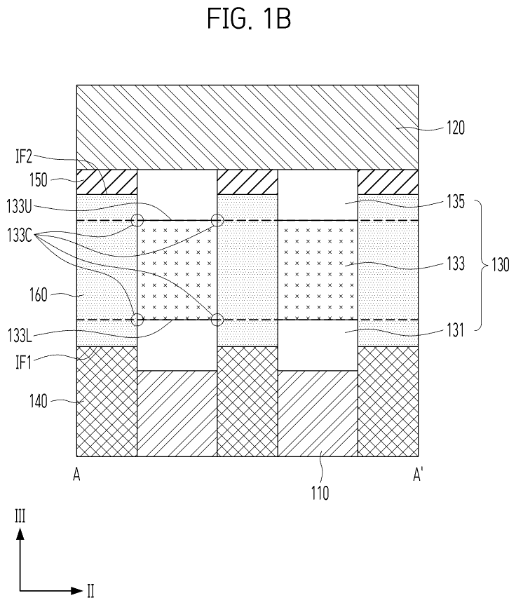

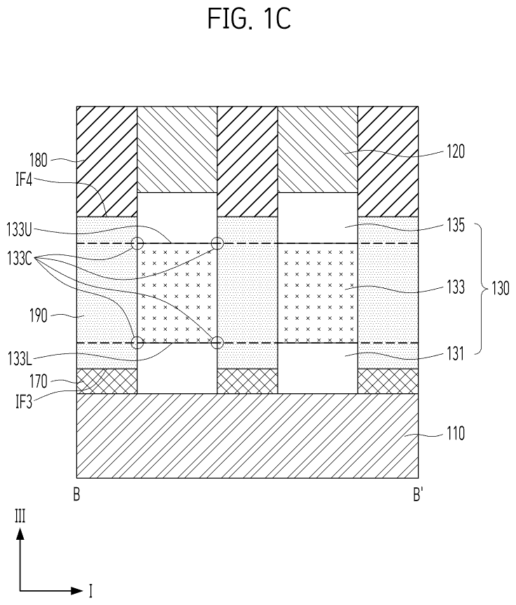

FIGS. 1A to 1C are drawings illustrating a semiconductor device according to an embodiment of the present disclosure. FIG. 1A is a plan view, FIG. 1B is a cross-sectional view taken along line A-A′ of FIG. 1A, FIG. 1C is a cross-sectional view taken along line B-B′ of FIG. 1A.

Referring to FIGS. 1A to 1C, the semiconductor device may include first conductive lines 110, second conductive lines 120, and memory cells 130. The semiconductor device may further include first gap-fill patterns 140, second gap-fill patterns 150, third gap-fill patterns 160, fourth gap-fill patterns 170, fifth gap-fill patterns 180, and sixth gap-fill patterns 190.

The first conductive lines 110 may each extend in a first direction I. The second conductive lines 120 may intersect the first conductive lines 110 and may be positioned on the first conductive lines 110. The second conductive lines 120 may each extend in a second direction II intersecting the first direction I. For example, the first conductive lines 110 may each be a word line, and the second conductive lines 120 may be a bit line. As another example, the first conductive lines 110 may each be a bit line, and the second conductive lines 120 may each be a word line.

The memory cells 130 may be arranged in the first direction I and the second direction II. The memory cell 130 may be positioned between the first conductive line 110 and the second conductive line 120. The memory cell 130 may include a variable resistance pattern 133. The memory cell 130 may further include at least one of a first electrode pattern 131 or a second electrode pattern 135.

The first electrode pattern 131 may be a portion of the first conductive line 110 or may be electrically connected to the first conductive line 110. The second electrode pattern 135 may be a portion of the second conductive line 120 or may be electrically connected to the second conductive line 120. The first electrode pattern 131 or the second electrode pattern 135 may include a conductive material such as carbon or metal. For example, the first electrode pattern 131 and/or the second electrode pattern 135 may include carbon. As another example, the first electrode pattern 131, or the second electrode pattern 135, or both may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pb), platinum (Pt), molybdenum (Mo), ruthenium (Ru), and the like, and may include a combination thereof.

The variable resistance patterns 133 may be respectively positioned between the first conductive lines 110 and the second conductive lines 120. The variable resistance pattern 133 may maintain an amorphous state during a program operation and may not change into a crystalline state after the program operation. In other words, a phase of the variable resistance pattern 133 may not change after the program operation. In this case, the variable resistance pattern 133 may be used as a data storage and as a selection element simultaneously. The variable resistance pattern 133 may include a resistive material and may have a characteristic of reversibly changing between different resistance states according to an applied voltage or current. For example, the variable resistance pattern 133 may include a variable resistance material of which a resistance changes without a phase change and may include a chalcogenide element. The variable resistance pattern 133 may include germanium (Ge), antimony (Sb), arsenic (As), silicon (Si), indium (In), tin (Sn), gallium (Ga), and the like, or may include a combination thereof.

For reference, although not shown in present drawing, the semiconductor device may further include a third electrode pattern and a switching pattern. For example, the semiconductor device may include a structure in which the first electrode pattern 131, the switching pattern, the third electrode pattern, the variable resistance pattern 133, and the second electrode pattern 135 are sequentially stacked. In this case, the first electrode pattern 131, the switching pattern, and the third electrode pattern may configure a selection element. The selection element may be a diode, a PNP diode, a transistor, a vertical transistor, a bipolar junction transistor (BJT), a metal insulator transition (MIT) element, a mixed ionic-electronic conduction (MIEC) element, an ovonic threshold switching (OTS) element, or the like. For example, the switching pattern may include a chalcogenide material. In addition, the third electrode pattern, the variable resistance pattern 133, and the second electrode pattern 135 may configure a memory element. The memory element and the selection element may share the third electrode pattern. The variable resistance pattern 133 may include a chalcogenide material.

The first gap-fill patterns 140 may be positioned between the first conductive lines 110 adjacent in the second direction II. For example, a first gap-fill pattern 140 may be positioned between an adjacent pair of the first conductive lines 110 in the second direction II. The first gap-fill patterns 140 may extend between the first electrode patterns 131 adjacent in the second direction II. The first gap-fill patterns 140 may include an insulating material such as an oxide. For example, the first gap-fill patterns 140 may include at least one of a tetra ethyl ortho silicate (TEOS) or a spin-on low K (SOL) material.

The second gap-fill pattern 150 may be positioned on the first gap-fill pattern 140. The second gap-fill patterns 150 may be positioned between second electrode patterns 135 adjacent to each other in the second direction II. For example, a second gap-fill patterns 150 may be positioned between an adjacent pair of the second electrode patterns 135 in the second direction II. The second gap-fill patterns 150 may include the same material as the first gap-fill patterns 140. In other words, the second gap-fill patterns 150 may include a material common with that of the first gap-fill patterns 140. For example, the second gap-fill patterns 150 may include an oxide and may include at least one of a TEOS or SOL material.

The third gap-fill pattern 160 may be positioned between the first gap-fill pattern 140 and the second gap-fill pattern 150. For example, an interface (or a first interface) IF1 of the third gap-fill pattern 160 with the first gap-fill pattern 140 may be positioned below a lower surface 133L of the variable resistance pattern 133, and an interface (or a second interface) IF2 of the third gap-fill pattern 160 with the second gap-fill pattern 150 may be positioned above an upper surface 133U of the variable resistance pattern 133. In other words, in the second direction II, the third gap-fill pattern 160 may cover all four corners 133C of the variable resistance pattern 133. Through this, even though program and erase operations of the memory cell 130 are repeatedly performed, separation of a material included in the variable resistance pattern 133 to an outside of the memory cell 130 through the four corners 133C may be prevented or reduced.

The third gap-fill pattern 160 may include a material different from that of the first gap-fill pattern 140. For example, the third gap-fill pattern 160 may include a nitride. The third gap-fill pattern 160 may include at least one of a silicon boron nitride layer (SiBN) or a silicon carbon nitride layer (SiCN). In other words, in the second direction II, the four corners 133C of the variable resistance pattern 133 may be covered with a nitride. In this case, compared to a case where the four corners 133C of the variable resistance pattern 133 are covered with an oxide, deterioration due to performing repeated operations of the memory cell 130 may be reduced. This is because material properties (e.g., modulus, hardness, etch selectivity, etc.) of nitride are superior to oxide. However, the third gap-fill pattern 160 is not limited to including the silicon boron nitride layer (SiBN) or the silicon carbon nitride layer (SiCN), and may include another type of silicon nitride layer according to embodiments of the present disclosure.

The fourth gap-fill patterns 170 may be positioned on the first conductive line 110. The fourth gap-fill patterns 170 may be positioned between the first electrode patterns 131 adjacent in the first direction I. For example, a fourth gap-fill pattern 170 may be positioned between an adjacent pair of the first electrode patterns 131 in the first direction I. The fourth gap-fill patterns 170 may include the same material as the first gap-fill patterns 140. For example, the fourth gap-fill patterns 170 may include an oxide, and may include at least one of a tetra ethyl ortho silicate (TEOS) or a spin-on low K (SOL) material.

The fifth gap-fill pattern 180 may be positioned on the fourth gap-fill pattern 170. The fifth gap-fill patterns 180 may be positioned between the second conductive lines 120 adjacent in the first direction I. For example, a fifth gap-fill pattern 180 may be positioned between an adjacent pair of the second conductive lines 120 in the first direction I. The fifth gap-fill patterns 180 may extend between the second electrode patterns 135 adjacent in the first direction I. The fifth gap-fill patterns 180 may include the same material as the fourth gap-fill patterns 170.

The sixth gap-fill pattern 190 may be positioned between the fourth gap-fill pattern 170 and the fifth gap-fill pattern 180. For example, an interface (or a third interface) IF3 of the sixth gap-fill pattern 190 with the fourth gap-fill pattern 170 may be positioned below the lower surface 133L of the variable resistance pattern 133, and an interface (or a fourth interface) IF4 of the sixth gap-fill pattern 190 with the fifth gap-fill pattern 180 may be positioned above the upper surface 133U of the variable resistance pattern 133. In other words, in the first direction I, the sixth gap-fill pattern 190 may cover all four corners 133C of the variable resistance pattern 133. Through this, separation of a material included in the variable resistance pattern 133 to an outside of the memory cell 130 through the four corners 133C according to repeatedly performing program and erase operations of the memory cell 130 may be prevented or reduced.

The sixth gap-fill pattern 190 may include a material different from that of the fourth gap-fill pattern 170. For example, the sixth gap-fill pattern 190 may include a nitride, and may include at least one of a silicon boron nitride layer (SiBN) or a silicon carbon nitride layer (SiCN). In other words, in the first direction I, the four corners 133C of the variable resistance pattern 133 may be covered with a nitride. In this case, compared to a case where the four corners 133C of the variable resistance pattern 133 are covered with an oxide, deterioration due to performing repeated operations of the memory cell 130 may be reduced. However, the sixth gap-fill pattern 190 is not limited to including the silicon boron nitride layer (SiBN) or the silicon carbon nitride layer (SiCN), and may include another type of silicon nitride layer according to embodiments of the present disclosure.

According to the structure described above, in the second direction II, the third gap-fill pattern 160 may cover the four corners 133C of the variable resistance pattern 133 with a nitride. In addition, in the first direction I, the sixth gap-fill pattern 160 may cover the four corners 133C of the variable resistance pattern 133 with a nitride. In this case, even though program and erase operations of the memory cell 130 are repeatedly performed, deterioration of the memory cell 130 may be reduced, and separation of a material included in the variable resistance pattern 133 to an outside of the memory cell 130 through the corners 133C of the variable resistance pattern 133 may be prevented or reduced.

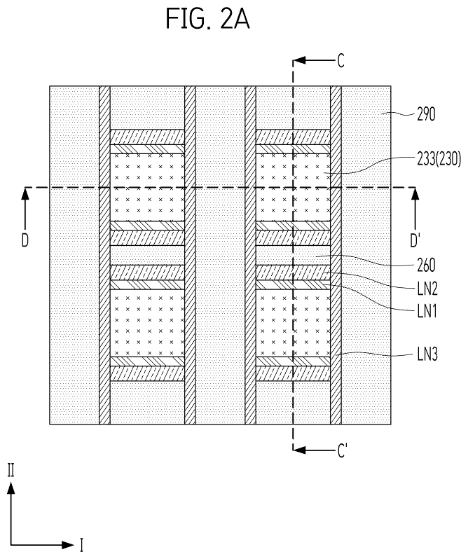

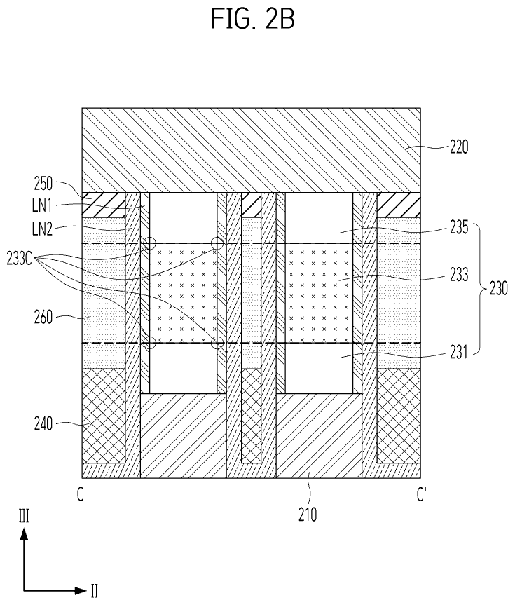

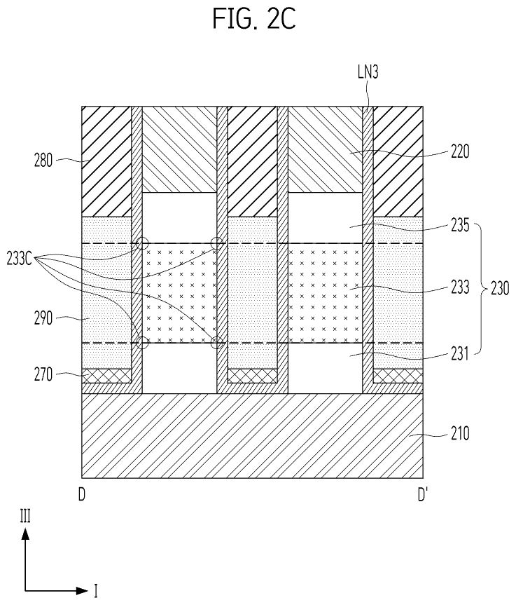

FIGS. 2A to 2C are drawings illustrating a semiconductor device according to an embodiment of the present disclosure. FIG. 2A is a plan view, FIG. 2B is a cross-sectional view taken along line C-C′ of FIG. 2A, and FIG. 2C is a cross-sectional view taken along line D-D′ of FIG. 2A. Hereinafter, a content that overlaps the content described above is omitted.

Referring to FIGS. 2A to 2C, the semiconductor device may include first conductive lines 210, second conductive lines 220, memory cells 230, first gap-fill patterns 240, second gap-fill patterns 250, third gap-fill patterns 260, fourth gap-fill patterns 270, fifth gap-fill patterns 280, and sixth gap-fill patterns 290. The semiconductor device may further include first liner patterns LN1, second liner patterns LN2, and third liner patterns LN3.

The first conductive lines 210 may each extend in the first direction I. The second conductive lines 220 may intersect the first conductive lines 210 and may be positioned on the first conductive lines 210. The second conductive lines 220 may each extend in the second direction II intersecting the first direction I.

The memory cells 230 may be arranged in the first direction I and the second direction II intersecting the first direction I. The memory cell 230 may be positioned between the first conductive line 210 and the second conductive line 220. The memory cell 230 may include a first electrode pattern 231, a second electrode pattern 235, and a variable resistance pattern 233. Here, the variable resistance pattern 233 may be positioned between the first electrode pattern 231 and the second electrode pattern 235.

The first liner patterns LN1 may each cover a sidewall of a corresponding one of the memory cells 230. Specifically, a first liner pattern LN1 may cover a substantially entire sidewall of a memory cell 230 adjacent to the first linear pattern LN1. For example, the first liner patterns LN1 may respectively cover corresponding sidewalls of the memory cell 230 that are adjacent in the second direction II. The first liner patterns LN1 may protect the memory cells 230 in a process of manufacturing the semiconductor device. The first liner patterns LN1 may each include a nitride, and may each include at least one of a silicon boron nitride layer (SiBN) or a silicon carbon nitride layer (SiCN).

The second liner patterns LN2 may be positioned on the first liner patterns LN1. The second liner patterns LN2 may each extend along a sidewall of a corresponding one of the first conductive lines 210. For example, a second liner pattern LN2 may extend along a sidewall of a first conductive line 210 adjacent to the second linear pattern LN2. The second liner patterns LN2 may protect the memory cells 230 in the process of manufacturing the semiconductor device. The second liner patterns LN2 may include a nitride, and may include at least one of a silicon boron nitride layer (SiBN) or a silicon carbon nitride layer (SiCN).

The third liner patterns LN3 may cover one or more sidewalls of the memory cells 230. For example, the third liner patterns LN3 may cover the sidewalls that are adjacent in the first direction I of the memory cells 230. Specifically, a third liner pattern LN3 may cover sidewalls of a pair of adjacent memory cells 230 in the first direction I. Moreover, the third liner pattern LN3 may extend in the second direction II to cover sidewalls of the memory cells 230 arranged in the second direction II. The third liner patterns LN3 may protect the memory cells 230 in the process of manufacturing the semiconductor device. The third liner patterns LN3 may include a nitride, and may include at least one of a silicon boron nitride layer (SiBN) or a silicon carbon nitride layer (SiCN).

For reference, the first, second, and third liner patterns LN1, LN2, and LN3 are not limited to including the silicon boron nitride layer (SiBN) or the silicon carbon nitride layer (SiCN), and may include another type of silicon nitride layer according to embodiments of the present disclosure.

The first gap-fill pattern 240 may be positioned on the second liner pattern LN2. For example, the first gap-fill pattern 240 may be positioned on a sidewall of the second liner pattern LN2. The first gap-fill pattern 240 may be positioned between the first conductive lines 210 adjacent in the second direction II. The second gap-fill pattern 250 may be positioned on the first gap-fill pattern 240, and may be positioned between the second electrode patterns 235 adjacent in the second direction II. At least one of the first gap-fill pattern 240 or the second gap-fill pattern 250 may include an oxide, and may include at least one of a tetra ethyl ortho silicate (TEOS) or a spin-on low K (SOL) material.

The third gap-fill pattern 260 may be positioned on the second liner pattern LN2. For example, the third gap-fill pattern 260 may be positioned on a sidewall of the second liner pattern LN2. The third gap-fill pattern 260 may be positioned between the first gap-fill pattern 240 and the second gap-fill pattern 250. An interface of the third gap-fill pattern 260 with the first gap-fill pattern 240 may be positioned below a lower surface of the variable resistance pattern 233, and an interface of the third gap-fill pattern 260 with the second gap-fill pattern 250 may be positioned above an upper surface of the variable resistance pattern 233.

The third gap-fill pattern 260 may include a material different from that of the first gap-fill pattern 240. In addition, the third gap-fill pattern 260 may include a material that is the same as at least one of the first liner pattern LN1 or the second liner pattern LN2. For example, the third gap-fill pattern 260 may include a nitride, and may include at least one of a silicon boron nitride layer (SiBN) or a silicon carbon nitride layer (SiCN).

The fourth gap-fill pattern 270 may be positioned between the first electrode patterns 231 adjacent in the first direction I. The fifth gap-fill pattern 280 may be positioned on the fourth gap-fill pattern 270, and may be positioned between the second conductive lines 220 adjacent in the first direction I. At least one of the fourth gap-fill pattern 270 or the fifth gap-fill pattern 280 may include the same material as the first gap-fill pattern 240.

The sixth gap-fill pattern 290 may be positioned on the third liner pattern LN3. For example, the sixth gap-fill pattern 290 may be positioned on a sidewall of the third liner pattern LN3. The sixth gap-fill pattern 290 may be positioned between the fourth gap-fill pattern 270 and the fifth gap-fill pattern 280. For example, an interface of the sixth gap-fill pattern 290 with the fourth gap-fill pattern 270 may be positioned below the lower surface of the variable resistance pattern 233, and an interface of the sixth gap-fill pattern 290 with the fifth gap-fill pattern 280 may be positioned above the upper surface of the variable resistance pattern 233.

The sixth gap-fill pattern 290 may include a material different from that of the fourth gap-fill pattern 270. In addition, the sixth gap-fill pattern 290 may include the same material as the third liner pattern LN3. For example, the sixth gap-fill pattern 290 may include a nitride, and may include at least one of a silicon boron nitride layer (SiBN) or a silicon carbon nitride layer (SiCN).

In the embodiment of FIGS. 2A to 2C, it is described that a first boundary surface between the first liner pattern LN1 and the second liner pattern LN2, and a second boundary surface between the second liner pattern LN2 and the third gap-fill pattern 260 exist, but embodiments of the present disclosure are not limited thereto. For example, the first liner pattern LN1, the second liner pattern LN2, and the third gap-fill pattern 260 may be formed in separate processes, but may include the same material, and thus the first liner pattern LN1, the second liner pattern LN2, and the third gap-fill pattern 260 may be formed as a single integrated body without forming a boundary surface therebetween. Similarly, a boundary surface between the third liner pattern LN3 and the sixth gap-fill pattern 290 may not exist.

Although the first liner pattern LN1 and the second liner pattern LN2 may cover corners 233C of the variable resistance pattern 233 in a line shape, the third gap-fill pattern 260 may be additionally formed, and thus the first and second liner patterns LN1 and LN2 and the third gap-fill pattern 260 may cover the corners 233C of the variable resistance pattern 233 in the second direction II with a sufficient thickness of nitride. Similarly, the third liner pattern LN3 and the sixth gap-fill pattern 290 may cover the corners 233C of the variable resistance pattern 233 in the first direction I with a sufficient thickness of nitride. In this case, even though the program and erase operations of the memory cell 230 are repeatedly performed, deterioration of the memory cell 230 may be prevented or reduced, and separation of a material included in the variable resistance pattern 233 to an outside of the memory cell 230 through the corners 233C may be prevented or reduced.

According to the embodiment described above, the semiconductor device may include the first liner pattern LN1, the second liner pattern LN2, and the third gap-fill pattern 260. Here, the first liner pattern LN1, the second liner pattern LN2, and the third gap-fill pattern 260 may include a nitride. Similarly, the semiconductor device may include the third liner pattern LN3 and the sixth gap-fill pattern 290. The third liner pattern LN3 and the sixth gap-fill pattern 290 may include a nitride.

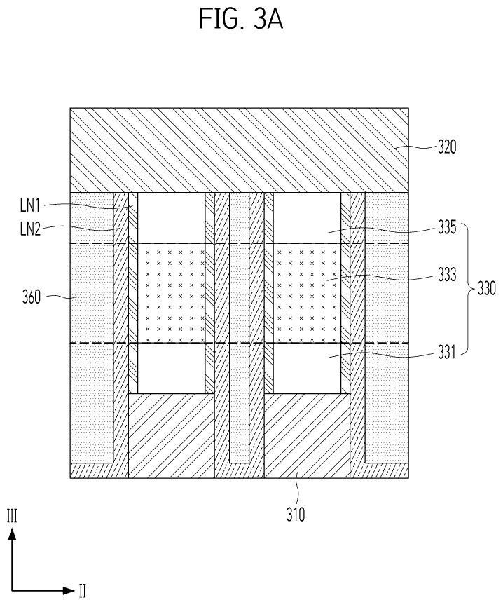

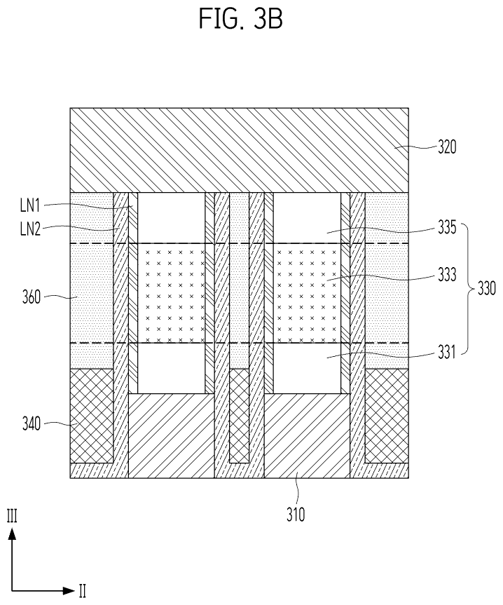

FIGS. 3A and 3B are drawings illustrating a semiconductor device according to an embodiment of the present disclosure. Hereinafter, a content that overlaps with the content described above may be omitted for the interest of brevity.

Referring to FIG. 3A, the semiconductor device may include a first conductive line 310, a second conductive line 320, a memory cell 330, a third gap-fill pattern 360, a first liner pattern LN1, and a second liner pattern LN2.

The third gap-fill pattern 360 may be positioned on the second liner pattern LN2. In other words, the third gap-fill pattern 360 including a nitride may be positioned on the second liner pattern LN2. Here, a lower surface of the third gap-fill pattern 360 may be positioned below a lower surface of the variable resistance pattern 333. In addition, an upper surface of the third gap-fill pattern 360 may be positioned above an upper surface of the variable resistance pattern 333. A process may be simplified and a time and cost for manufacturing the semiconductor device may be reduced by forming the third gap-fill pattern 360 on the second liner pattern LN2 with a single material.

In addition, because all of the first liner pattern LN1, the second liner pattern LN2, and the third gap-fill pattern 360 include a nitride, and cover all corners of the variable resistance pattern 333, deterioration of the memory cell 330 may be prevented or reduced, and separation of a material of the variable resistance pattern 333 to an outside of the memory cell 330 through the corners may be prevented or reduced.

Referring to FIG. 3B, the semiconductor device may further include a first gap-fill pattern 340. Here, the first gap-fill pattern 340 may include an oxide. The third gap-fill pattern 360 may be positioned on the first gap-fill pattern 340. Here, an interface between the first gap-fill pattern 340 and the third gap-fill pattern 360 may be positioned below the lower surface of the variable resistance pattern 333. An upper surface of the third gap-fill pattern 360 may be positioned above the upper surface of the variable resistance pattern 333.

When the third gap-fill pattern 360 is formed with a single material on the second liner pattern LN2, a void may be formed in the third gap-fill pattern 360 below the lower surface of the variable resistance pattern 333. Therefore, by forming the first gap-fill pattern 340 before forming the third gap-fill pattern 360, formation of a void in the third gap-fill pattern 360 may be substantially prevented.

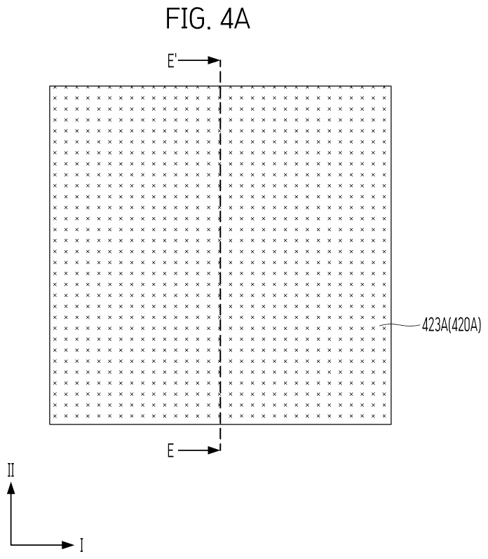

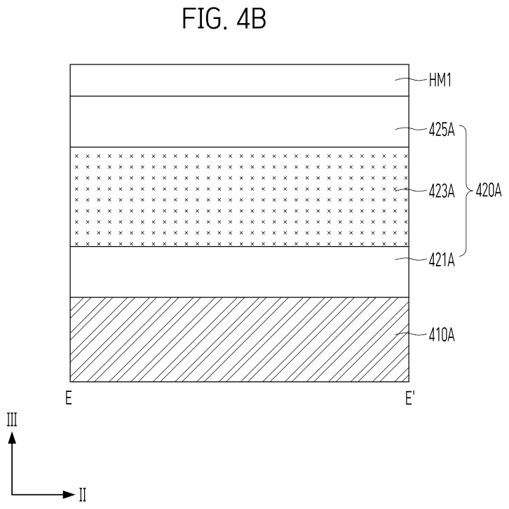

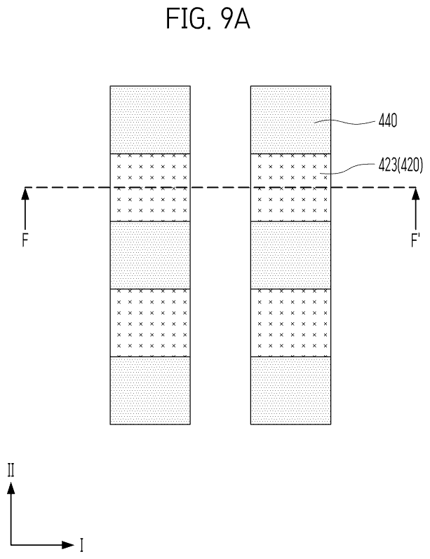

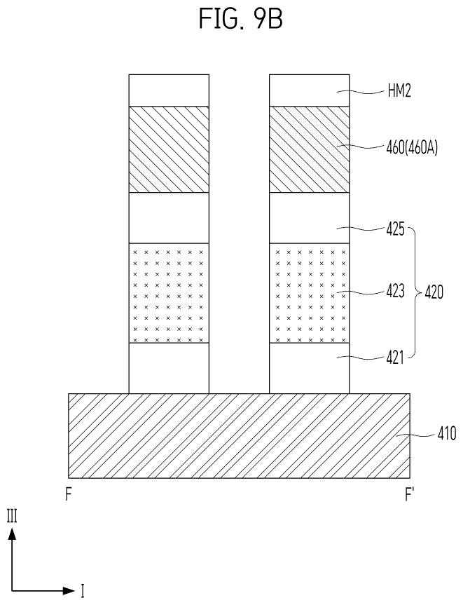

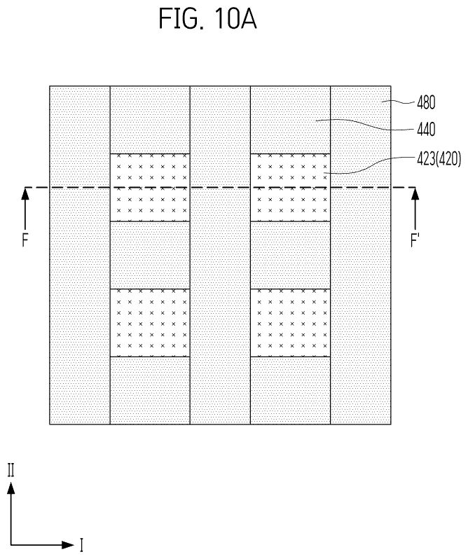

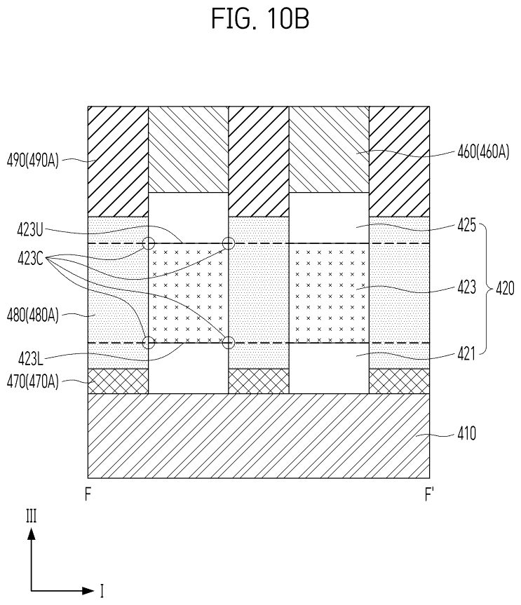

FIGS. 4A to 10B are drawings illustrating a method of manufacturing a semiconductor device according to an embodiment of the present disclosure. FIGS. 4A, 5A, 6A, 7A, 8A are plan views, and FIGS. 4B, 5B, 6B, 7B, and 8B are cross-sectional views taken along lines E-E′ of FIGS. 4A to 8A, respectively. FIGS. 9A and 10A are plan views, and FIGS. 9B and 10B are cross-sectional views taken along lines F-F′ of FIGS. 9A and 10A, respectively. Hereinafter, a content that overlaps the content described above may be omitted for the interest of brevity.

Referring to FIGS. 4A and 4B, a memory layer 420A including a variable resistance layer 423A may be formed on a first conductive layer 410A. First, a first electrode layer 421A may be formed on the first conductive layer 410A. Subsequently, a variable resistance layer 423A may be formed on the first electrode layer 421A. Subsequently, a second electrode layer 425A may be formed on the variable resistance layer 423A. Here, the variable resistance layer 423A may include a chalcogenide material.

For reference, although not shown in present drawing, the memory layer 420A may be formed by sequentially stacking the first electrode layer 421A, a switching layer, a third electrode layer, the variable resistance layer 423A, and the second electrode layer 425A.

Subsequently, a first hard mask pattern HM1 may be formed on the memory layer 420A. The first hard mask pattern HM1 may prevent or reduce damage to the memory layer 420A in a subsequent process as a protective pattern.

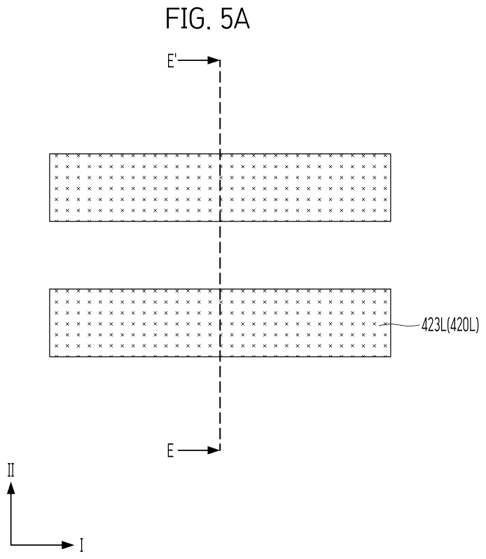

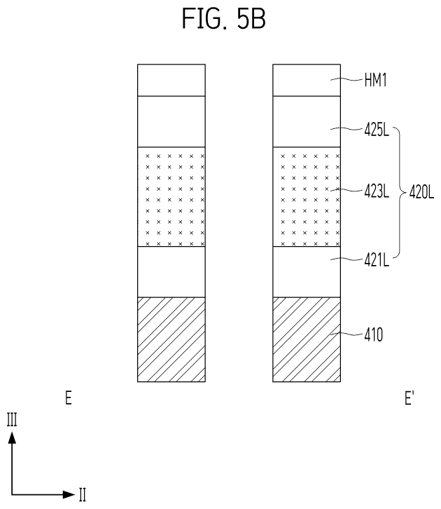

Referring to FIGS. 5A and 5B, memory lines 420L including variable resistance lines 425L may be formed. First, the second electrode layer 425A, the variable resistance layer 423A, and the first electrode layer 421A may be sequentially etched to form second electrode lines 425L, variable resistance lines 423L, and first electrode lines 421L each extending in the first direction I.

Subsequently, first conductive lines 410 may be formed. For example, the first conductive layer 410A may be etched through the first hard mask pattern HM1 to form the first conductive lines 410 each extending in the first direction I. For reference, when etching the memory layer 420A, etching the conductive layer 410A simultaneously is possible.

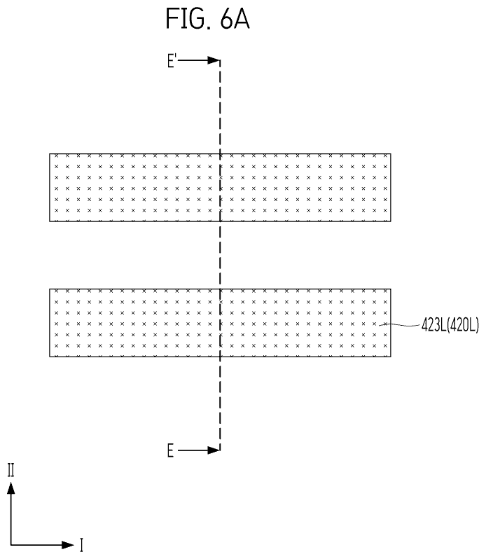

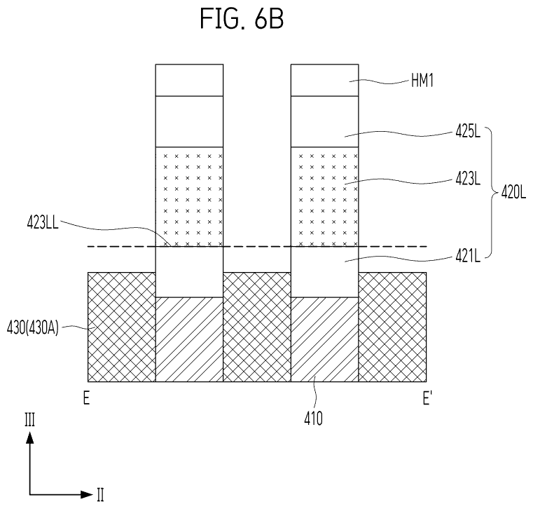

Referring to FIGS. 6A and 6B, a first gap-fill pattern 430 may be formed between the first conductive lines 410. For example, the first gap-fill pattern 430 may be formed so that an upper surface of the first gap-fill pattern 430 is positioned below a lower surface 423LL of the variable resistance lines 423L between the first conductive lines 410. Specifically, a first gap-fill pattern 430 may be formed between an adjacent pair of the first conductive lines 410, so that an upper surface of the first gap-fill pattern 430 is positioned below a lower surface 423LL of each of an adjacent pair of the variable resistance lines 423L. First, a preliminary first gap-fill pattern 430A may be coated between the first conductive lines 410. Specifically, the preliminary first gap-fill pattern 430A may be coated to fill a space between the adjacent pair of the first conductive lines 410, so that an upper surface of the preliminary first gap-fill pattern 430A is positioned below the lower surface 423LL of each of the adjacent pair of the variable resistance lines 423L. For example, the preliminary first gap-fill pattern 430A may be coated by a spin coating method. Subsequently, the preliminary first gap-fill pattern 430A may be cured to form the first gap-fill pattern 430. For example, the first gap-fill pattern 430 may be formed by curing the preliminary first gap-fill pattern 430A by baking using an oven and UV cutting. Here, the first gap-fill pattern 430 may include an insulating material such as an oxide. For example, the first gap-fill pattern 430 may include at least one of a tetra ethyl ortho silicate (TEOS) material or a spin-on low K (SOL) material. However, embodiments of the present disclosure are not limited thereto, and a process of forming the preliminary first gap-fill pattern 430A may be omitted. For example, the first gap-fill pattern 430 may be formed using a deposition method.

For reference, although not shown in the present drawing, in a process of forming the preliminary first gap-fill pattern 430A and the first gap-fill pattern 430, residue may be formed on sidewalls of the memory lines 420L. In this case, before forming a second gap-fill pattern 440 in a subsequent process, the residue formed on the sidewalls of the memory lines 420L may be removed so that the upper surface of the first gap-fill pattern 430 is positioned below the lower surface 423LL of each of the variable resistance lines 423L.

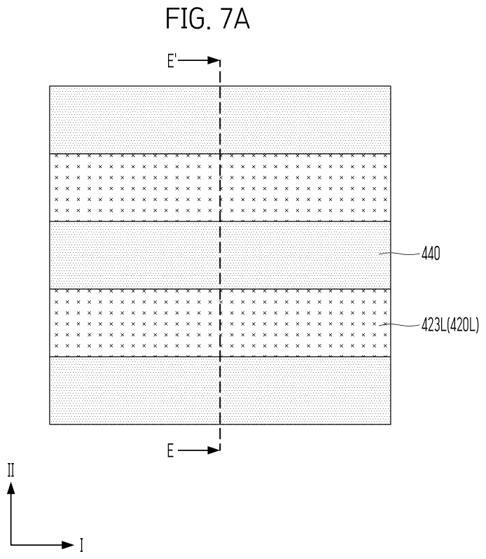

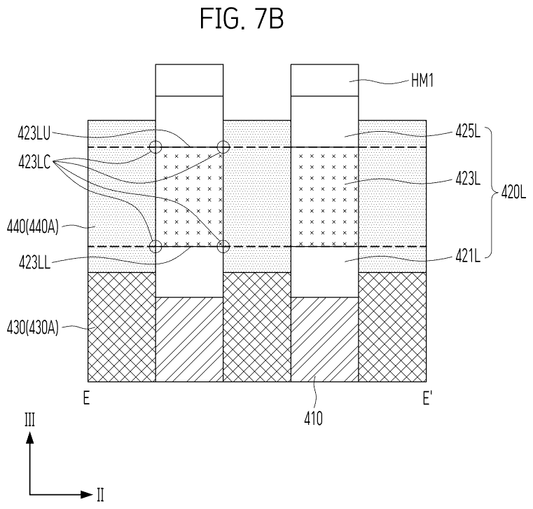

Referring to FIGS. 7A and 7B, the second gap-fill pattern 440 may be formed on the first gap-fill pattern 430. For example, the second gap-fill pattern 440 may be formed so that an upper surface of the second gap-fill pattern 440 is positioned above an upper surface 423LU of each of the variable resistance lines 423L on the first gap-fill pattern 430. First, a second gap-fill layer 440A may be deposited on the first gap-fill pattern 430. For example, the second gap-fill layer 440A may be deposited so as to fill between the variable resistance lines 423L. Subsequently, the second gap-fill layer 440A may be etched to form the second gap-fill pattern 440 so that the upper surface of the second gap-fill pattern 440 is positioned above the upper surface 423LU of each of the variable resistance lines 423L (e.g., an adjacent pair of the variable resistance lines 423L).

Here, the second gap-fill pattern 440 may include a material different from that of the first gap-fill pattern 430. The second gap-fill pattern 440 may include an insulating material such as a nitride. For example, the second gap-fill pattern 440 may include at least one of a silicon boron nitride layer (SiBN) or a silicon carbon nitride layer (SiCN).

In this case, the second gap-fill pattern 440 may cover all corners 423LC of the variable resistance line 423L. For example, the second gap-fill pattern 440 may cover all four corners 423LC of the variable resistance lines 423L in the second direction II with nitride.

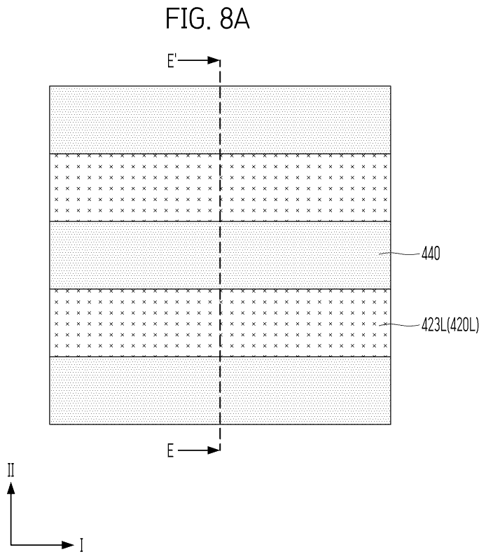

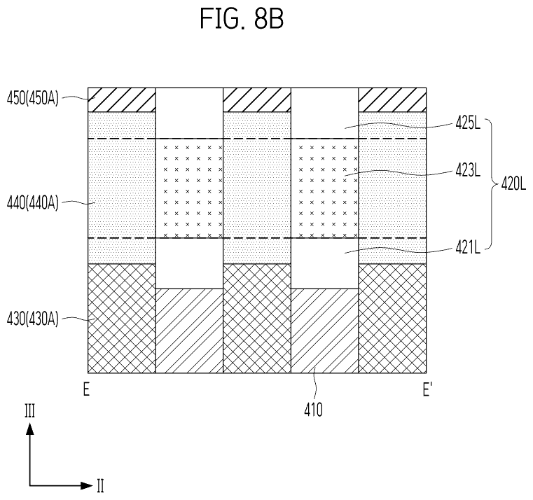

Referring to FIGS. 8A and 8B, a third gap-fill pattern 450 may be formed on the second gap-fill pattern 440. First, a preliminary third gap-fill pattern 450A may be coated on the second gap-fill pattern 440. Subsequently, the preliminary third gap-fill pattern 450A may be cured to form the third gap-fill pattern 450.

Here, the third gap-fill pattern 450 may include the same material as the first gap-fill pattern 430. For example, the third gap-fill pattern 450 may include an oxide, and may include at least one of a TEOS material or an SOL material.

Subsequently, planarization may be performed so that the second electrode lines 425L are exposed. For example, the first hard mask pattern HM1 may be removed. In addition, the third gap-fill pattern 450 may be planarized so that an upper surface of each of the second electrode lines 425L is exposed.

Referring to FIGS. 9A and 9B, second conductive lines 460 may be formed. First, a second conductive layer 460A may be formed on the memory lines 420L. Subsequently, the second conductive layer 460A may be etched to form the second conductive lines 460 each extending in the second direction II that intersects the first direction I.

For reference, a second hard mask pattern HM2 may be formed on the second conductive layer 460A. The second hard mask pattern HM2 may prevent or reduce damage to the memory lines 420L in a subsequent process as a protective pattern.

Subsequently, memory cells 420 including variable resistance patterns 425 may be formed. For example, the second electrode lines 425L, the variable resistance lines 423L, and the first electrode lines 421L may be sequentially etched to form second electrode patterns 425, variable resistance patterns 423, and first electrode patterns 421.

Referring to FIGS. 10A and 10B, a fourth gap-fill pattern 470 may be formed so that an upper surface of the fourth gap-fill pattern 470 is positioned below a lower surface 423L of each of the variable resistance patterns 423. First, a preliminary fourth gap-fill pattern 470A may be coated between the first electrode patterns 421. Subsequently, the preliminary fourth gap-fill pattern 470A may be cured to form the fourth gap-fill pattern 470. Here, the fourth gap-fill pattern 470 may include the same material as the first gap-fill pattern 430.

Subsequently, a fifth gap-fill pattern 480 may be formed so that an upper surface of the fifth gap-fill pattern 480 is positioned above an upper surface 423U of each of the variable resistance patterns 423 on the fourth gap-fill pattern 470. First, a fifth gap-fill layer 480A may be deposited. Subsequently, the fifth gap-fill layer 480A may be etched to form the fifth gap-fill pattern 480. Here, the fifth gap-fill pattern 480 may include a material different from that of the fourth gap-fill pattern 470. For example, the fifth gap-fill pattern 480 may include a nitride, and may include at least one of a silicon boron nitride layer (SiBN) or a silicon carbon nitride layer (SiCN).

In this case, the fifth gap-fill pattern 480 may cover all corners 423C of the variable resistance pattern 423. For example, the fifth gap-fill pattern 480 may cover all four corners 423C of the variable resistance pattern 423 in the first direction I with a nitride.

Subsequently, a sixth gap-fill pattern 490 may be formed on the fifth gap-fill pattern 480. First, a preliminary sixth gap-fill pattern 490A may be coated on the fifth gap-fill pattern 480. Subsequently, the preliminary sixth gap-fill pattern 490A may be cured to form the sixth gap-fill pattern 490. Here, the sixth gap-fill pattern 490 may include the same material as the fourth gap-fill pattern 470.

Subsequently, planarization may be performed so that the second conductive lines 460 are exposed. For example, the second hard mask pattern HM2 may be removed. In addition, the sixth gap-fill pattern 490 may be planarized so that an upper surface of each of the second conductive lines 460 is exposed.

According to an embodiment of the present disclosure, the fifth gap-fill pattern 480 may cover all four corners 423C of the variable resistance pattern 423 with a nitride in the first direction I, and the second gap-fill pattern 440 may cover all four corners of the variable resistance pattern 423 with a nitride in the second direction II. In this case, even though program and erase operations of the memory cell 420 are repeatedly performed, separation of a material included in the variable resistance pattern 423 to an outside of the memory cell 420 through the corners 423C may be prevented or reduced.

In addition, the second gap-fill pattern 440 and the fifth gap-fill pattern 480 may include a nitride. In this case, compared to a case where the corners of the variable resistance pattern 423 are covered with an oxide, deterioration due to repeated operations of the memory cell 420 may be reduced. This is because one or more material properties (e.g., modulus, hardness, etch selectivity, etc.) of the nitride is superior to the oxide.

According to the manufacturing method described above, the second gap-fill pattern 440 and the fifth gap-fill pattern 480 surrounding sidewalls of the variable resistance pattern 423 and including a nitride may be formed. In particular, the second gap-fill pattern 440 may cover all four corners of the variable resistance pattern 423 with a nitride in the second direction II, and the fifth gap-fill pattern 480 may cover all four corners 423C of the variable resistance pattern 423 with a nitride in the first direction I. Therefore, deterioration due to repeated operations of the memory cell 420 may be reduced, and separation of a material of the variable resistance pattern 423 to an outside of the memory cell 420 through the corners may be prevented or reduced.

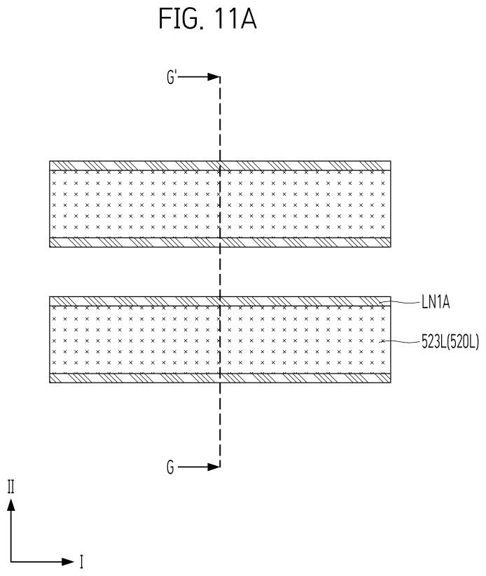

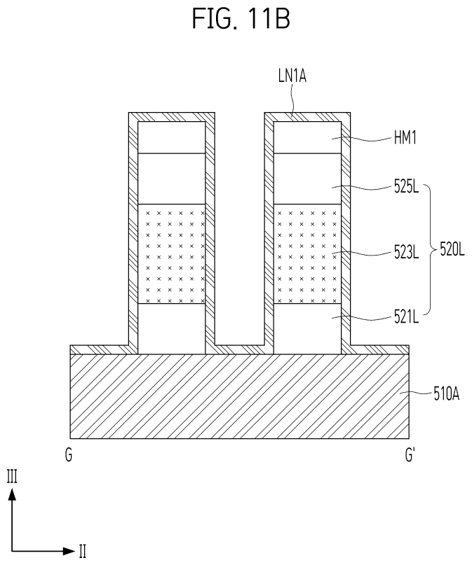

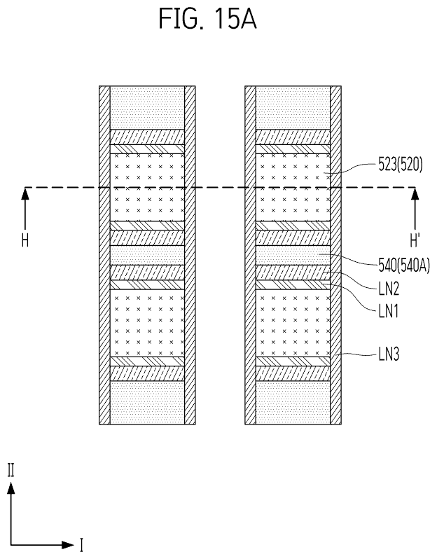

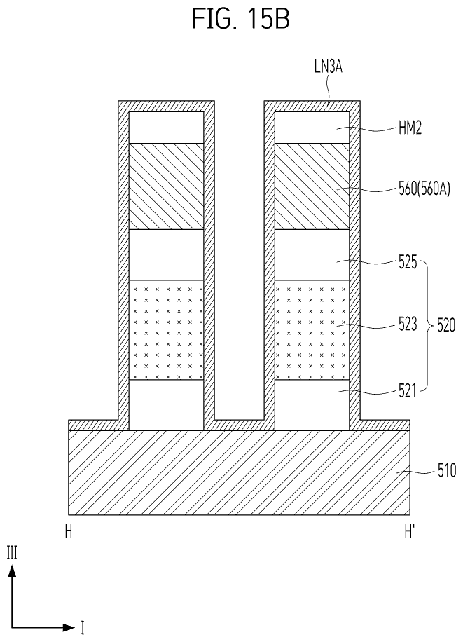

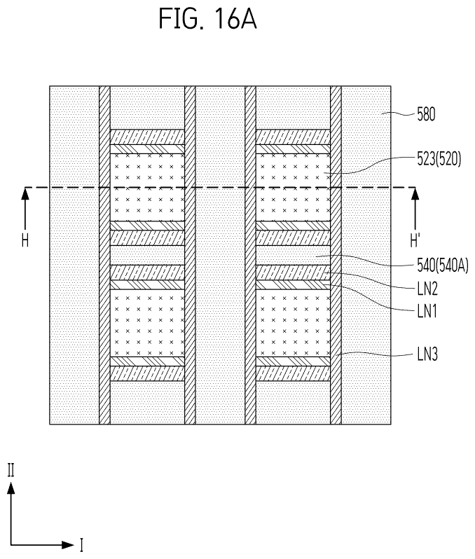

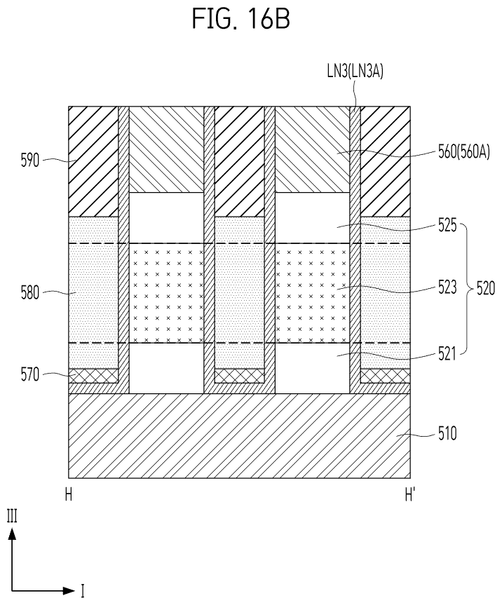

FIGS. 11A to 16B are drawings illustrating a method of manufacturing a semiconductor device according to an embodiment of the present disclosure. FIGS. 11A, 12A, 13A, and 14A are plan views, and FIGS. 11B, 12B, 13B, and 14B are cross-sectional views taken along lines G-G′ of FIGS. 11A, 12A, 13A, and 14A, respectively. FIGS. 15A and 15B are plan views, and FIGS. 15B and 16B are cross-sectional views taken along lines H-H′ of FIGS. 15A and 15B, respectively. Hereinafter, a content that overlaps the content described above may be omitted for the interest of brevity.

Referring to FIGS. 11A and 11B, a memory layer may be formed on a first conductive layer 510A. For example, the memory layer may be formed by sequentially stacking a first electrode layer, a variable resistance layer, and a second electrode layer on the first conductive layer 510A. Here, the variable resistance layer may include a chalcogenide material. Subsequently, a first hard mask pattern HM1 may be formed on the memory layer.

Subsequently, the memory layer may be etched to form memory lines 520L. For example, the second electrode layer, the variable resistance layer, and the first electrode layer may be sequentially etched to form second electrode lines 525L, variable resistance lines 523L, and first electrode lines 521L.

Subsequently, a first liner layer LN1A may be formed on the memory lines 520L. For example, the first liner layer LN1A may be conformally formed along the memory lines 520L and the first conductive layer 510A. Specifically, the first liner layer LN1A may be conformally formed along an upper surface of the first conductive layer 510A, sidewalls of the memory lines 520L, and sidewalls and upper surfaces of the first hard mask patterns HM1. The first liner layer LN1A may prevent or reduce damage to the memory lines 520L in a subsequent process.

The first liner layer LN1A may include an insulating material such as a nitride. For example, the first liner layer LN1A may include at least one of a silicon boron nitride layer (SiBN) or a silicon carbon nitride layer (SiCN).

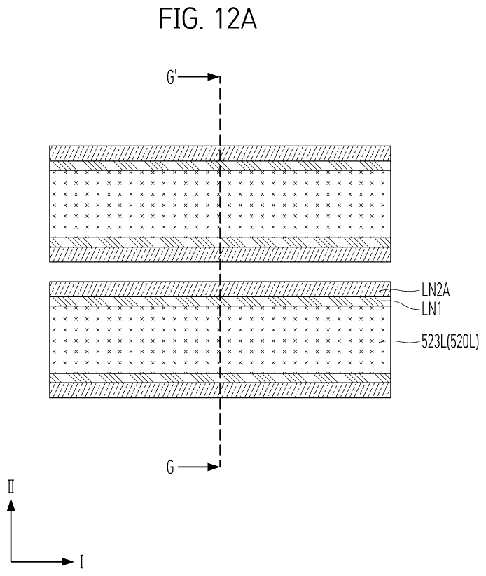

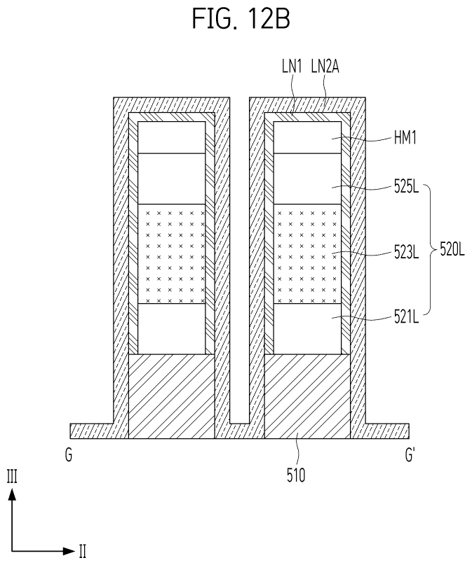

Referring to FIGS. 12A and 12B, the first liner layer LN1A may be etched to form first liner patterns LN1. For example, lower portions of the first liner layer LN1A contacting the first conductive layer 510A may be etched to form the first liner patterns LN1 so that the first conductive layer 510A is exposed.

Subsequently, the first conductive layer 510A may be etched to form first conductive lines 510 extending in the first direction I. In a process of etching the first conductive layer 510A to form the first conductive lines 510, the first liner patterns LN1 may protect the memory lines 520L.

Subsequently, a second liner layer LN2A may be formed on the first liner patterns LN1. For example, the second liner layer LN2A extending along the first conductive lines 510 may be formed on the first liner patterns LN1. Specifically, the second line layer LN2A may be formed on sidewalls of the first conductive lines 510 and on the first liner patterns LN1. The second liner layer LN2A may prevent or reduce damage to the memory lines 520L and the first conductive lines 510 in a subsequent process.

The second liner layer LN2A may include the same material as the first liner patterns LN1. For example, the second liner layer LN2A may include a nitride, and may include at least one of a silicon boron nitride layer (SiBN) or a silicon carbon nitride layer (SiCN).

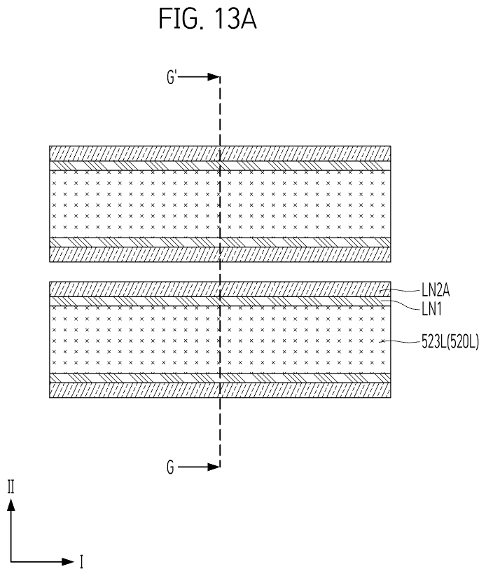

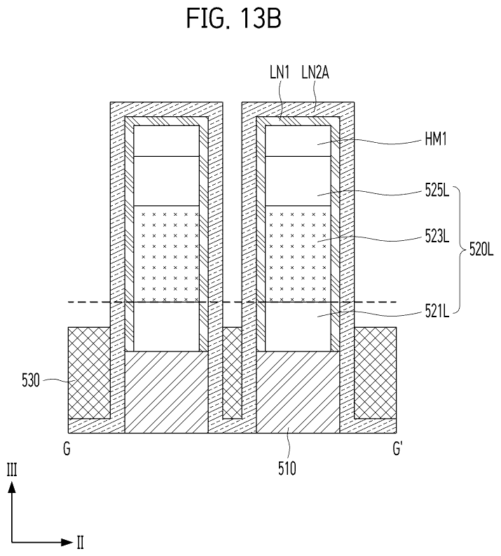

Referring to FIGS. 13A and 13B, a first gap-fill pattern 530 may be formed on the second liner layer LN2A. The first gap-fill pattern 530 may be formed similarly to the method of forming the first gap-fill pattern 430 of FIGS. 6A and 6B. For example, the first gap-fill pattern 530 may be formed so that an upper surface is positioned below a lower surface of the variable resistance line 523L.

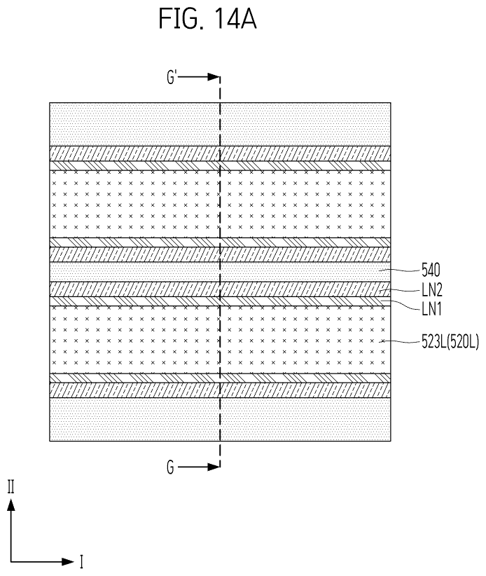

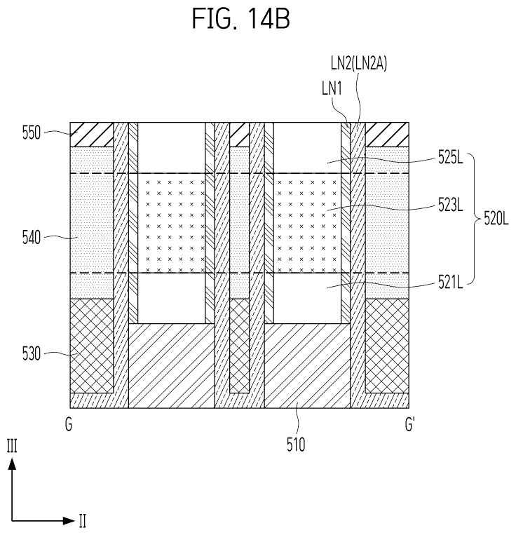

Referring to FIGS. 14A and 14B, a second gap-fill pattern 540 may be formed on the first gap-fill pattern 530. The second gap-fill pattern 540 may be formed similarly to the method of forming the second gap-fill pattern 440 of FIGS. 7A and 7B. For example, the second gap-fill pattern 540 may be formed so that an upper surface is positioned above an upper surface of the variable resistance line 523L.

The second gap-fill pattern 540 may include the same material as the first liner patterns LN1 and the second liner layer LN2A. For example, the second gap-fill pattern 540 may include a nitride, and may include at least one of a silicon boron nitride layer (SiBN) or a silicon carbon nitride layer (SiCN).

In this case, a boundary surface may not exist between the first liner pattern LN1, the second liner layer LN2A, and the second gap-fill pattern 540. In other words, because the first liner pattern LN1, the second liner layer LN2A, and the second gap-fill pattern 540 may be formed in separate processes but may include the same material, the first liner pattern LN1, the second liner layer LN2A, and the second gap-fill pattern 540 may be formed as a single integrated body without forming a boundary surface therebetween.

The first liner pattern LN1 and the second liner layer LN2A may cover all corners of the variable resistance line 523L in a line shape with a nitride, but a thickness thereof may not be sufficient. In order to compensate for this, the second gap-fill pattern 540 including a nitride may be additionally formed. That is, the first liner pattern LN1, the second liner layer LN2A, and the second gap-fill pattern 540 may cover the corners of the variable resistance line 523L in the second direction II with a sufficient thickness of nitride.

Subsequently, a third gap-fill pattern 550 may be formed on the second gap-fill pattern 540. The third gap-fill pattern 550 may be formed similarly to the method of forming the third gap-fill pattern 450 of FIGS. 8A and 8B.

Subsequently, planarization may be performed so that the second electrode lines 525L are exposed. For example, the first hard mask pattern HM1 may be removed, and the third gap-fill pattern 550 may be planarized so that an upper surface of each of the second electrode lines 525L is exposed. In this process, an upper surface of the second liner layer LN2A may be etched to form second liner patterns LN2.

Referring to FIGS. 15A and 15B, second conductive lines 560 may be formed. First, a second conductive layer 560A may be formed on the memory lines 520L. Subsequently, the second conductive layer 560A may be etched to form the second conductive lines 560 each extending in the second direction II that intersects the first direction I.

Subsequently, memory cells 520 including the variable resistance patterns may be formed. For example, the second electrode lines 525L, the variable resistance lines 523L, and the first electrode lines 521L may be sequentially etched to form the second electrode patterns 525, the variable resistance patterns 523, and the first electrode patterns 521.

Subsequently, a third liner layer LN3A may be formed on the memory cells 520. For example, the third liner layer LN3A may be formed on the variable resistance patterns 523. The third liner layer LN3A may prevent or reduce damage to the memory cells 520 in a subsequent process.

The third liner layer LN3A may include an insulating material such as a nitride. For example, the third liner layer LN3A may include at least one of a silicon boron nitride layer (SiBN) or a silicon carbon nitride layer (SiCN).

Referring to FIGS. 16A and 16B, a fourth gap-fill pattern 570 may be formed on the third liner layer LN3A. For example, the fourth gap-fill pattern 570 may be formed so that an upper surface of the fourth gap-fill pattern 570 is positioned below a lower surface of each of an adjacent pair of the variable resistance patterns 523. Subsequently, a fifth gap-fill pattern 580 may be formed on the fourth gap-fill pattern 570. For example, the fifth gap-fill pattern 580 may be formed on the fourth gap-fill pattern 570 so that an upper surface of the fifth gap-fill pattern 580 is positioned above an upper surface of each of the adjacent pair of the variable resistance patterns 523. Subsequently, a sixth gap-fill pattern 590 may be formed on the fifth gap-fill pattern 580. For reference, the fourth gap-fill pattern 570, the fifth gap-fill pattern 580, and the sixth gap-fill pattern 590 may be formed similarly to the method of forming the fourth gap-fill pattern 470, the fifth gap-fill pattern 480, and the sixth gap-fill pattern 490 of FIGS. 10A and 10B.

Subsequently, planarization may be performed so that the second conductive lines 560 are exposed. For example, a second hard mask pattern HM2 may be removed, and the sixth gap-fill pattern 590 may be planarized so that upper surfaces of the second conductive lines 560 is exposed. In this process, upper portions of the third liner layer LN3A may be etched to form third liner patterns LN3.

Here, the fifth gap-fill pattern 580 may include the same material as the third liner pattern LN3. In this case, a boundary surface between the third liner pattern LN3 and the fifth gap-fill pattern 580 may not exist. The third liner pattern LN3 may cover all corners of the variable resistance pattern 523 in a line shape with a nitride, but a thickness thereof may not be sufficient, and in order to compensate for this, the fifth gap-fill pattern 580 including a nitride may be additionally formed.

That is, the first liner pattern LN1, the second liner pattern LN2, and the second gap-fill pattern 540 may cover the corners of the variable resistance pattern 523 in the second direction II with a sufficient thickness of nitride. The third liner layer LN3A and the fifth gap-fill pattern 580 may cover the corners of the variable resistance pattern 523 in the first direction I with a sufficient thickness of nitride.

In this case, even though program and erase operations of the memory cell 520 are repeatedly performed, deterioration of the memory cell 520 may be prevented or reduced, and separation of a material included in the variable resistance pattern 523 to an outside of the memory cell 520 through the corners may be prevented or reduced.

For reference, in the embodiment of FIGS. 11A to 16B, formation of the first gap-fill pattern 530, the second gap-fill pattern 540, the third gap-fill pattern 550, the fourth gap-fill pattern 570, the fifth gap-fill pattern 580, and the sixth gap-fill pattern 590 is described, but a partial configuration among these may be omitted according to embodiments of the present disclosure.

For example, the first gap-fill pattern 530 and the third gap-fill pattern 550 may be omitted and the second gap-fill pattern 540 may be formed on the second liner layer LN2A. Similarly, the fourth gap-fill pattern 570 and the sixth gap-fill pattern 590 may be omitted and the fifth gap-fill pattern 580 may be formed on the third liner layer LN3A.

In this case, because a process of forming the first gap-fill pattern 530 and the third gap-fill pattern 550 is omitted, the second gap-fill pattern 540 is formed, a process of forming the fourth gap-fill pattern 570 and the sixth gap-fill pattern 590 is omitted, and the fifth gap-fill pattern 580 is formed, a process time and process cost may be reduced.

As another example, the third gap-fill pattern 550 may be omitted, and the second gap-fill pattern 540 may be formed on the first gap-fill pattern 530. Similarly, the sixth gap-fill pattern 590 may be omitted, and the fifth gap-fill pattern 580 may be formed on the third liner layer LN3A on the fourth gap-fill pattern 570.

When the second gap-fill pattern 540 is formed with a single material on the second liner layer LN2A and the fifth gap-fill pattern 580 is formed with a single material on the third liner layer LN3A, a void may be formed inside the second gap-fill pattern 540 or the fifth gap-fill pattern 580 under a lower surface of the variable resistance pattern 523. Therefore, the first gap-fill pattern 530 may be formed before forming the second gap-fill pattern 540, and the fourth gap-fill pattern 570 may be formed before forming the fifth gap-fill pattern 580. Therefore, a void may be substantially prevented from being formed inside the second gap-fill pattern 540 or the fifth gap-fill pattern 580.

According to the manufacturing method described above, the first and second liner patterns LN1 and LN2 and the second gap-fill pattern 540 covering the corners of the variable resistance pattern 523 in the second direction II may be formed. In addition, the third liner pattern LN3 and the fifth gap-fill pattern 580 covering the corners of the variable resistance pattern 523 in the first direction I may be formed. In this case, even though the program and erase operations of the memory cell 520 are repeatedly performed, deterioration of the memory cell 520 may be prevented or reduced, and separation of a material included in the variable resistance pattern 523 to an outside of the memory cell 520 through the corners may be prevented or reduced.

Although some specific embodiments of the present disclosure have been described with reference to the accompanying drawings, embodiments of the present disclosure are not limited to the above-described embodiments. Various substitution, modification, and change of the embodiments may be possible by those skilled in the art to which the present disclosure belongs, and these also belong to the scope of the present disclosure.

What is claimed is:

1. A semiconductor device comprising:
first conductive lines each extending in a first direction;
second conductive lines positioned on the first conductive lines and each extending in a second direction that intersects the first direction;
memory cells respectively positioned between the first conductive lines and the second conductive lines, and each including a variable resistance pattern;
a first gap-fill pattern positioned between an adjacent pair of the first conductive lines in the second direction;
a second gap-fill pattern positioned on the first gap-fill pattern; and
a third gap-fill pattern positioned between the first gap-fill pattern and the second gap-fill pattern, the third gap-fill pattern having a first interface with the first gap-fill pattern and a second interface with the second gap-fill pattern, the first interface being positioned below a lower surface of the variable resistance pattern, and the second interface being positioned above an upper surface of the variable resistance pattern.

2. The semiconductor device of claim 1, further comprising:
first liner patterns each covering a sidewall of a corresponding one of the memory cells; and
second liner patterns positioned on the first liner patterns and each extending along a sidewall of a corresponding one of the first conductive lines.

3. The semiconductor device of claim 2, wherein at least one of the first liner patterns or the second liner patterns includes a material that is common with that of the third gap-fill pattern.

4. The semiconductor device of claim 1, wherein the first gap-fill pattern includes a material that is common with that of the second gap-fill pattern, and
wherein the third gap-fill pattern includes a material different from that of the first gap-fill pattern.

5. The semiconductor device of claim 4, wherein the first gap-fill pattern includes an oxide, and
wherein the third gap-fill pattern includes a nitride.

6. The semiconductor device of claim 5, wherein the first gap-fill pattern includes at least one of a tetra ethyl ortho silicate (TEOS) or a spin-on low K (SOL) material, and
wherein the third gap-fill pattern includes at least one of a silicon boron nitride layer (SiBN) or a silicon carbon nitride layer (SiCN).

7. A semiconductor device comprising:
first conductive lines each extending in a first direction;
second conductive lines positioned on the first conductive lines and each extending in a second direction that intersects the first direction;
memory cells respectively positioned between the first conductive lines and the second conductive lines, and each including a variable resistance pattern;
a first gap-fill pattern positioned between an adjacent pair of the first conductive lines in the second direction, and including an oxide; and
a third gap-fill pattern positioned on the first gap-fill pattern, the third gap-fill pattern having a lower surface positioned below a lower surface of the variable resistance pattern, and having an upper surface positioned above an upper surface of the variable resistance pattern.

8. The semiconductor device of claim 7, further comprising:
a second gap-fill pattern positioned on the third gap-fill pattern.

9. The semiconductor device of claim 8, wherein a first interface of the third gap-fill pattern with the first gap-fill pattern is positioned below the lower surface of the variable resistance pattern, and
wherein a second interface of the third gap-fill pattern with the second gap-fill pattern is positioned above the upper surface of the variable resistance pattern.

10. The semiconductor device of claim 8, wherein the second gap-fill pattern includes a material that is common with that of the first gap-fill pattern.

11. The semiconductor device of claim 7, wherein the first gap-fill pattern includes at least one of a tetra ethyl ortho silicate (TEOS) or a spin-on low K (SOL) material, and
wherein the third gap-fill pattern includes at least one of a silicon boron nitride layer (SiBN) or a silicon carbon nitride layer (SiCN).

12. The semiconductor device of claim 7,
first liner patterns each covering a sidewall of a corresponding one of the memory cells; and
second liner patterns positioned on the first liner patterns and each extending along a sidewall of a corresponding one of the first conductive lines.

13. The semiconductor device of claim 12, wherein at least one of the first liner patterns or the second liner patterns includes a material that is common with that of the third gap-fill pattern.

14. A method of manufacturing a semiconductor device, the method comprising:
forming a variable resistance layer on a first conductive layer;
forming variable resistance lines by etching the variable resistance layer;
forming first conductive lines each extending in a first direction by etching the first conductive layer;
forming a first gap-fill pattern between an adjacent pair of the first conductive lines so that an upper surface of the first gap-fill pattern is positioned below a lower surface of each of an adjacent pair of the variable resistance lines; and
forming a second gap-fill pattern on the first gap-fill pattern so that an upper surface of the second gap-fill pattern is positioned above an upper surface of each of the adjacent pair of the variable resistance lines.

15. The method of claim 14, wherein forming the first gap-fill pattern comprises:
coating a preliminary first gap-fill pattern to fill a space between the adjacent pair of the first conductive lines so that an upper surface of the preliminary first gap-fill pattern is positioned below the lower surface of each of the adjacent pair of the variable resistance lines; and
forming the first gap-fill pattern by curing the preliminary first gap-fill pattern.

16. The method of claim 14, wherein forming the second gap-fill pattern comprises:
depositing a second gap-fill layer on the first gap-fill pattern; and
forming the second gap-fill pattern by etching the second gap-fill layer, so that the upper surface of the second gap-fill pattern is positioned above the upper surface of each of the adjacent pair of variable resistance lines.

17. The method of claim 14, further comprising:
forming a first liner layer on the variable resistance lines before forming the first conductive lines;
forming first liner patterns by etching the first liner layer;
forming the first conductive lines by etching the first conductive layer; and
forming a second liner layer on sidewalls of the first conductive lines and on the first liner patterns.

18. The method of claim 17, wherein at least one of the first liner layer or the second liner layer includes a material that is common with the second gap-fill pattern.

19. The method of claim 14, further comprising:
forming second conductive lines each extending in a second direction that intersects the first direction on the variable resistance lines;
forming variable resistance patterns by etching the variable resistance lines; and
forming a third liner layer on the variable resistance patterns.

20. The method of claim 19, further comprising:
forming a fourth gap-fill pattern so that an upper surface of the fourth gap-fill pattern is positioned below a lower surface of each of an adjacent pair of the variable resistance patterns;
forming a fifth gap-fill pattern on the fourth gap-fill pattern so that an upper surface of the fifth gap-fill pattern is positioned above an upper surface of each of the adjacent pair of the variable resistance patterns; and
forming a sixth gap-fill pattern on the fifth gap-fill pattern.

21. The method of claim 14, further comprising:
forming a third gap-fill pattern on the second gap-fill pattern.

22. The method of claim 21, wherein the first gap-fill pattern includes a material that is common with the third gap-fill pattern, and
wherein the second gap-fill pattern includes a material different from that of the first gap-fill pattern.

23. The method of claim 22, wherein the first gap-fill pattern includes an oxide, and
wherein the second gap-fill pattern includes a nitride.

24. The method of claim 23, wherein the first gap-fill pattern includes at least one of a tetra ethyl ortho silicate (TEOS) or a spin-on low K (SOL) material, and
wherein the third gap-fill pattern includes at least one of a silicon boron nitride layer (SiBN) or a silicon carbon nitride layer (SiCN).
